(19) United States
(12) Patent Application Publication
(10) Pub. No.: US 2022/0393437 A1
(43) Pub. Date: Dec. 8, 2022

(54) PRODUCTION METHOD FOR SEMICONDUCTOR DEVICE

(71) Applicant: Mitsubishi Electric Corporation, Tokyo (JP)

(72) Inventor: Mitsunori NAKATANI, Tokyo (JP)

(73) Assignee: Mitsubishi Electric Corporation, Tokyo (JP)

(21) Appl. No.: 17/756,334

(22) PCT Filed: Jan. 10, 2020
(86) PCT No.: PCT/JP2020/000658

§ 371 Date: May 23, 2022

(51) Int. Cl. H01S 5/227; G03F 7/40; G03F 7/32; G03F 7/004; H01L 21/027

(52) U.S. Cl. CPC H01S 5/2275; G03F 7/40; G03F 7/32; G03F 7/004; H01L 21/027

(57) ABSTRACT

A manufacturing method for semiconductor device comprises the steps of: forming a ridge on the surface of an InP substrate; applying a photoresist to the surface of the InP substrate so as to cover the ridge; exposing through a mask an area of the photoresist covering part of an electrode contact layer at the top of the ridge, to form a resist pattern by development; applying a shrink material so as to cover resist pattern defects occurred when forming the resist pattern; forming a crosslinked portion in the defects to repair them by reacting the shrink material with an acid remaining at the exposed interface of the resist pattern; and removing by etching an electrode contact layer exposed from the resist pattern having the repaired defects after stripping away an unreacted shrink material, thereby to obtain a desired processed shape.

### TECHNICAL FIELD

The present application relates to a manufacturing method for semiconductor device.

### BACKGROUND ARTS

A conventional optical semiconductor element has on the same substrate a mesa structure the same in size but different in elemental composition, accordingly complicating its manufacturing process. For example, prior Patent Document 1 discloses a method of forming a buried layer, in which after a vertically deposited structure, which is the base of the mesa structures, is formed by metal-organic vapor phase epitaxy (MOVPE), mesa stripes are formed by etching; then a portion except for above one of the mesa stripes desired to be altered is covered with a resist; then part of the mesa strip exposed by etching is removed to form a core layer; then the resist is removed; and then a semi-insulating layer is regrown by MOS' PE.

### PRIOR ART DOCUMENT

### Patent Document

Patent Document 1: JP2010-15382 A (Paragraph [0036] and FIG. 6)

### SUMMARY OF THE INVENTION

### Problem that the Invention is to Solve

In the method of Patent Document 1, however, when the resist pattern is registered using a photolithography technique, since a displacement by the amount of alignment precision occurs, problems are raised that are liable to cause failures due to left/right unevenness of the opening of the resist pattern with respect to the mesa, and due to exposure up to the side walls of the mesa and occurrence of remaining the resist by overexposure and underexposure. Moreover, since thickly applying the resist to cover the mesa step with the resist is liable to cause a failure due to a remaining resist, a severe conditions are imposed on the resist developing time and the like; accordingly, cracks are generated in the resist due to local stress occurring at the opening of the resist, thus raising a problem of leading to an etching failure.

The present application discloses a technology for resolving the problems as described above and aims at providing a manufacturing method for semiconductor device that reduces failure due to resist defects and thereby obtains a desired processed shape.

### Means for Solving the Problem

A manufacturing method for semiconductor device disclosed in the present application includes: a step of forming a ridge on a surface of an InP substrate; a step of applying a photoresist to a surface of the InP substrate so as to cover the ridge; a step of exposing through a mask an area of the photoresist covering part of an electrode layer at a top of the ridge, to form a resist pattern by development; a step of applying a shrink material so as to cover the resist pattern; a step of forming a crosslinked portion by reacting the shrink material with an acid remaining at an exposed interface of the resist pattern; and a step of removing by etching an electrode layer exposed from a resist pattern having the crosslinked portion formed after an unreacted shrink material other than the reacted shrink material is stripping away.

### Advantageous Effect of the Invention

According to the present application, it is possible to reduce a failure due to resist defects by forming a crosslinked portion using a shrink material to repair the defects occurred in a resist pattern for etching a top layer of the ridge, thereby obtaining a desired processed shape.

### BRIEF DESCRIPTION OF THE DRAWINGS

FIG. 1 is a plan view showing a structure of a semiconductor device manufactured by a manufacturing method for semiconductor device according to Embodiment 1;

FIG. 2 is a cross-sectional view showing the structure of the semiconductor device manufactured by the manufacturing method for semiconductor device according to Embodiment 1;

FIG. 3 is another cross-sectional view showing the structure of the semiconductor device manufactured by the manufacturing method for semiconductor device according to Embodiment 1;

FIG. 4 is a plan view showing the semiconductor device before processed by the manufacturing method for semiconductor device according to Embodiment 1;

FIG. 5 is a cross-sectional view showing the semiconductor device before processed by the manufacturing method for semiconductor device according to Embodiment 1;

FIG. 6 is a cross-sectional view showing a step of manufacturing the semiconductor device by the manufacturing method for semiconductor device according to Embodiment 1;

FIG. 7 a cross-sectional view showing a step of manufacturing the semiconductor device by the manufacturing method for semiconductor device according to Embodiment 1;

FIG. 8 a cross-sectional view showing a step of manufacturing the semi conductor device by the manufacturing method for semiconductor device according to Embodiment 1;

FIG. 9 a cross-sectional view showing a step of manufacturing the semiconductor device by the manufacturing method for semiconductor device according to Embodiment 1;

FIG. 10 a cross-sectional view showing a step of manufacturing the semiconductor device by the manufacturing method for semiconductor device according to Embodiment 1;

FIG. 11 a cross-sectional view showing a step of manufacturing the semiconductor device by the manufacturing method for semiconductor device according to Embodiment 1;

FIG. 12 is a flowchart showing the steps of manufacturing the semiconductor device by the manufacturing method for semiconductor device according to Embodiment 1; and

FIG. 13 is a plan view showing a step of manufacturing the semiconductor device by the manufacturing method for semiconductor device according to Embodiment 1.

### DETAILED DESCRIPTION OF THE INVENTION

### Embodiment 1

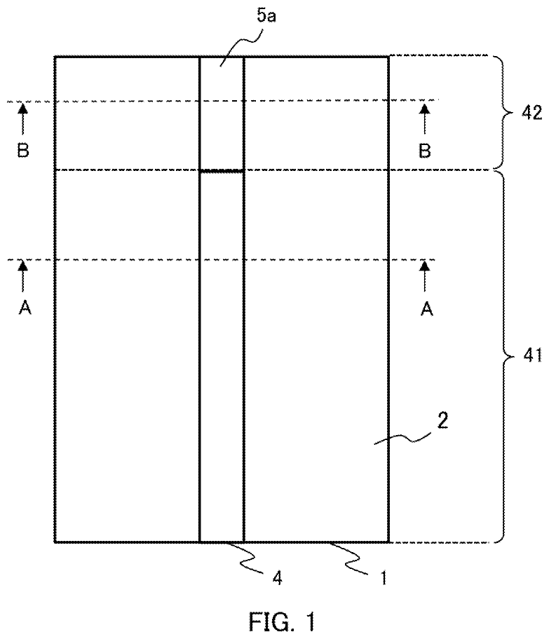

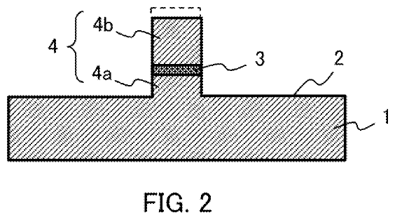

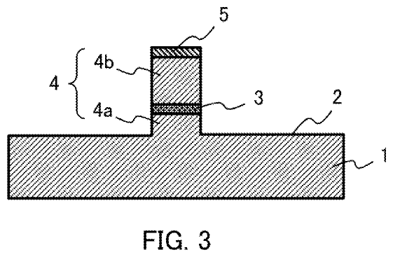

FIG. 1 is a plan view showing a semiconductor device after manufacturing steps using a manufacturing method for semiconductor device according to Embodiment 1 of the present application. FIG. 2 is a cross-sectional view taken in the direction of the arrows along the line A-A of FIG. 1, and FIG. 3 is another sectional view taken in the direction of the arrows along the line B-B of FIG. 1.

After the steps of manufacturing the semiconductor device using the manufacturing method for semiconductor device according to Embodiment 1, a laser diode (LD) section 41 with an electrode contact layer 5a being left at the top of a ridge 4 and a wavelength modulator section 42 with the electrode contact layer 5a being removed from the top of the ridge 4 are formed as shown in FIG. 1, and FIGS. 2, 3. In the optical semiconductor, since the LD section 41 is connected to the wavelength modulator section 42, the connection part of the electrode contact layer 5a needs to be removed because it is unnecessary.

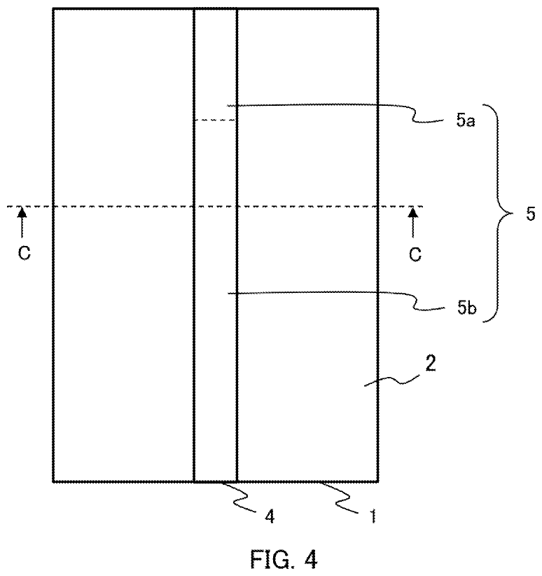

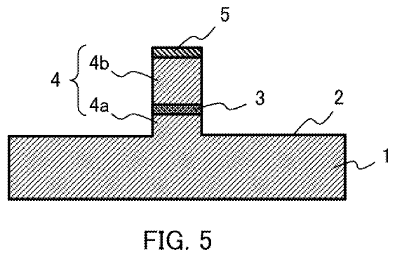

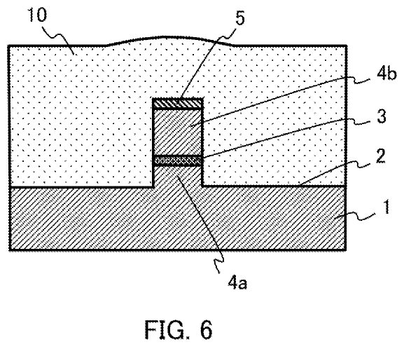

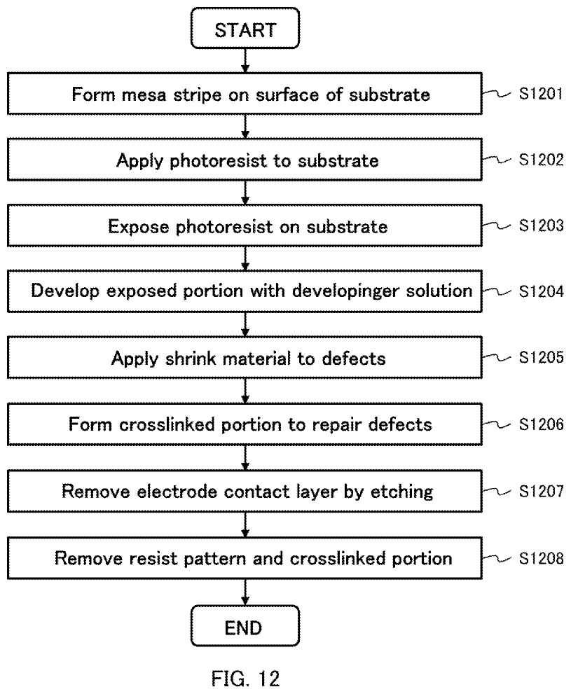

FIG. 4 is a plan view of the semiconductor device before processed in the steps of manufacturing the semiconductor device using the manufacturing method for semiconductor device according to Embodiment 1, and FIG. 5 is a cross-sectional view taken in the direction of the arrows along the line C-C of FIG. 4. FIG. 6 to FIG. 11 are cross-sectional views in each step of manufacturing the semiconductor device using the manufacturing method for semiconductor device according to Embodiment 1, and FIG. 12 is a flowchart showing the manufacturing steps in the manufacturing method for semiconductor device according to Embodiment 1. The manufacturing method is described hereinafter with reference to these figures.

First of all, using the manufacturing method described in Patent Document 1 (Paragraph [0036] and FIG. 6B), InP, InGaAs, and the like are deposited on the surface 2 of the InP substrate 1 by MOVPE and then etched to the InP substrate 1 with a protect mask, whereby a mesa stripe is formed that is made up of the deposited layers on a protrusion 4a of the InP substrate 1, as shown in FIGS. 4 and 5 (Step S1201). The mesa strip is structured such that a waveguide. (InGaAs) 3 is sandwiched between the part 4a and a part 4b of the ridge 4, and an electrode contact layer 5 is further disposed at the top of the ridge 4. While the electrode contact layer 5b of the LD section 41 is unnecessary and to be removed, the electrode contact layer 5a of the wavelength modulator section 42 is necessary. Since the step between the mesa stripe and the surface 2 of the substrate is as large as several μm, it is important in a resist process in semiconductor manufacturing to ensure coverability of the resist for the step and a focus margin when exposure.

Subsequently, a photoresist 10 is applied to the InP substrate 1 so as to cover the ridge 4 as shown in FIG. 6 (Step S1202). The photoresist 10 is prebaked after spin-coated flatly with the top of the ridge 4 being covered. The photoresist 10 includes such as Tokyo Ohka Kogyou's THMR®-iP1800 to 3650 series as positive resists having a sensitivity to the i-line (wavelength of 365 nm), and is treated at a heating temperature of 90° C. for a treatment time of 120 seconds using a hot plate after its thickness is adjusted by viscosity and spin speed. The photoresist 10 used here is composed of commonly used materials: a mixture of naphthoquinone diazide (NQD) photosensitizer, a novolak resin, and thinner for dissolving these to apply. Since most of the thinner evaporates during the prebake after the application, the photoresist 10 becomes composed mainly of the photosensitizer and the resin. Note that the resist is better to have a thickness larger than the step of the ridge 4 in consideration of step coverage depending on the mesa step.

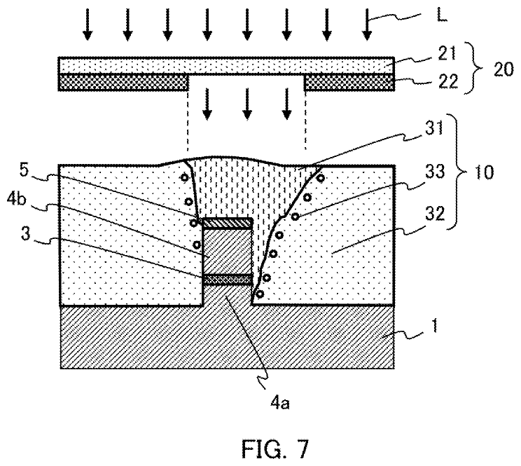

Next, the InP substrate 1 covered with the photoresist 10 and a mask 20 are registered with each other to expose the area of the photoresist 10 corresponding to the electrode contact layer 5b to be removed, as shown in FIG. 7 (Step S1203). The exposure is performed by irradiation of an i-line exposure light L. The mask 20 defines an exposure area by a light shielding mask 22 of a transparent glass mask 21. Although the mask 20 with the light shielding mask 22 having an aperture area corresponding to the top area of the electrode contact layer 5b to be removed is registered, the center is displaced by the amount of alignment deviation. The aperture width of the light shielding mask 22 needs to be determined from the relation to the amount of side etching during the etching. In Embodiment 1, the light shielding mask 22 is used that has an aperture width the same as or slightly wider than the top width of the ridge 4.

The photoresist 10 is divided into an exposed portion 31 and an unexposed portion 32 by being exposed to the exposure light L passing through the mask 20. The naphthoquinone diazide photosensitizer in the photoresist 10 is photodecomposed, to produces an acid 33. The photodecomposed acid 33 exists to a small extent at the interface between the unexposed portion 32 and the exposed portion 31 of the resist 10.

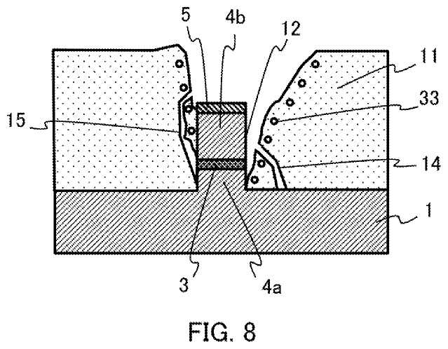

Subsequently, the exposed portion 31 is developed with a developer solution (step S1204). An alkaline developer solution, for example, tetramethylammonium hydroxide (TMAH) is used for the development, and water washing and drying are performed after the development. While the NQD photosensitizer in the unexposed portion 32 of the photoresist 10 permeates through the novolak resin polymers and prevents the unexposed portion from solving to the developer by intermolecular force, the NQD photosensitizer in the exposed portion 31 is photodecomposed into the acid 33 and the exposed portion thereby becomes in the condition apt to dissolve the alkaline developer solution. By taking advantage of difference in solubility between the exposed portion 31 and the unexposed portion 32, a desired resist pattern 11 is formed as shown in FIG. 8.

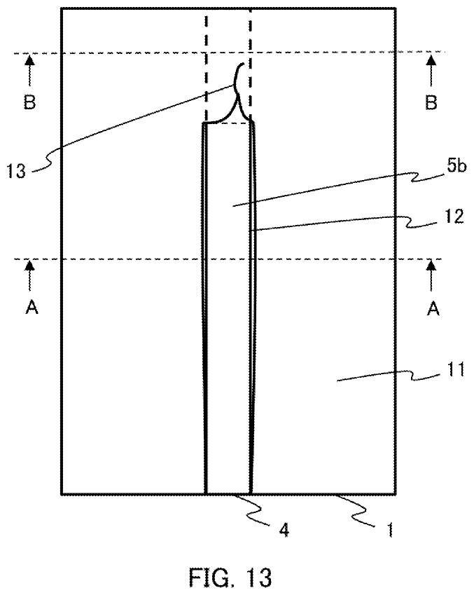

FIG. 13 is a plan view after the exposed portion 31 is developed with the developing solution. As shown in FIG. 13 and FIG. 8, by applying the photoresist 10 to the steps of the ridge 4 and by prebaking and then exposing it to a strong alkaline developer solution, local stress is likely to concentrate on the photoresist 10 adjacent the steps of the ridge 4, which may in some cases causes resist cracks 13, 14, 15. Moreover, a deep resist recess 12 is also liable to occur along the side walls of the ridge 4 due to a misalignment with respect to the steps of the ridge 4. The resist crack 13 extends to the unexposed portion 32 of the photoresist 10 on the electrode contact layer 5a of the wavelength modulator section 42 to be covered, thus resulting in that the electrode contact layer 5a cannot be covered. The resist recess 12 and the resist cracks 14, 15 expose the waveguide 3 to be covered. When the etching is performed with the presence of the defects of the resist recess 12 and the resist cracks 13, 14, 1.5, the electrode contact layer 5a and the waveguide 3 are abnormally etched, thus obtaining no desired device characteristics.

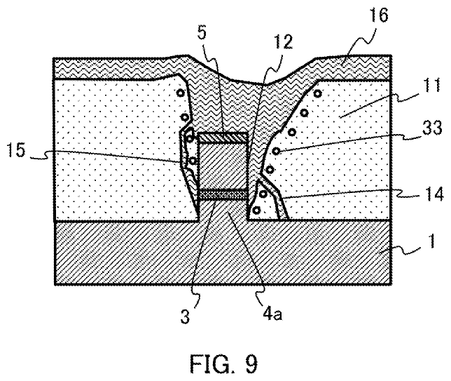

Hence, a defect repairing step is introduced next to repair the defects, in which step a shrink material 16 is applied to the defects as shown in FIG. 9 (Step S1205). The shrink material 16, which is a liquid material containing a crosslinking agent, is evenly applied by spin coating to the resist pattern 11 formed on the substrate to penetrate into interstices in the defects of the resist recess 12 and resist cracks 13, 14, 15. For the shrink material 16, a fine pattern forming material described in, for example, JP3071401B is used.

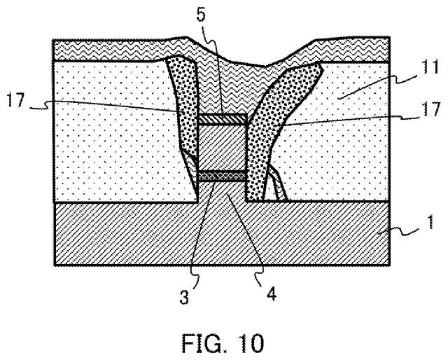

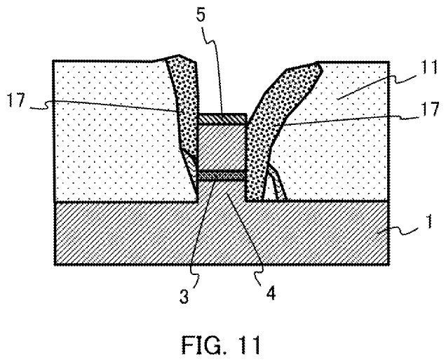

Subsequently, the shrink material 16 is reacted with the acid 33 remaining at the exposed interface of the resist pattern 11 to form a crosslinked portion 17, thereby to repair the defects, as shown in FIG. 10 (Step S1206). The shrink material 16, when prebaked at a heating temperature of 120° C. for a treatment time of 2 minutes using a hot plate, reacts with the acid 33 to form the crosslinked portion 17. Since the crosslinked portion cannot be stripped away such as by water washing, the defects are repaired by the shrink material. The unreacted shrink material 16 can be easily stripped away such as by water washing as shown in FIG. 11.

Finally, the unnecessary electrode contact layer 5b is removed by an etching (Step S1207), and then the resist pattern 11 and the crosslinked portion 17 are removed (Step S1208), so that a processed shape as shown in FIGS. 1, 2, 3 can be obtained.

In addition, the photoresist 10, while exemplified as a positive resist having sensitivity to the i-line, may be a resist as long as it generates an acid when irradiated with an exposure light and also the developer solution may be other than the alkaline developer solution.

In this way, by forming the crosslinked portion 17 using the shrink material 16 to repair defects occurred in the resist pattern 11 for etching the part of the top layer of the ridge 4, the failure due to the resist defects can be reduced, thus being able to obtain a desired processed shape.

As described above, the manufacturing method for semiconductor device according to Embodiment 1 includes: the step of forming the ridge 4 on the surface of the InP substrate 1; the step of applying the photoresist 10 to the surface of the InP substrate 1 so as to cover the ridge 4; the step of exposing through the mask 20 the area of the photoresist 10, covering part of an electrode contact layer 5 at the top of the ridge 4 and forming the resist pattern 11 by development; the step of applying the shrink material 16 so as to cover defects of the resist pattern 11 occurred when the resist pattern 11 is formed; the defects repairing step of repairing the defects by forming the crosslinked portion 17 in the defects by reacting the shrink material with the acid 33 remaining at the exposed interface of the resist pattern 11; and the step of removing by the etching the electrode contact layer 5b exposed from the resist pattern 11 having repaired defects after stripping away the unreacted shrink material 16, thus being able to reduce the failure due to resist defects and to obtain a desired processed shape.

Although the present application describes various exemplary embodiments and implementations, it should be understood that various features and aspects and functionalities described in one or more of the individual embodiments are not limited to their applicability to the specific embodiment but instead can be applied alone or in various combinations to one or more of the embodiments. Therefore, numerous modifications that have not been exemplified are conceivable without departing from the technical scope disclosed in the specification of the present application. For example, at least one of the constituent components may be modified, added, or eliminated, and further at least one of the constituent components mentioned in at least one of the preferred embodiments may be selected and combined with the other constituent elements mentioned in another preferred embodiment.

### REFERENCE NUMERALS

1: InP substrate;
2: surface;
3: waveguide;
4: ridge;
5b: electrode contact layer (electrode layer);
10: photoresist;
12: resist recesses (defects);
13, 14, 15: resist crack (defect);
16: shrink material;
17: crosslinked portion;
20: mask;
31: exposed portion; and
33: acid.

1. A manufacturing method for semiconductor device comprising:
a step of forming a ridge on a surface of an InP substrate;
a step of applying a photoresist to a surface of the InP substrate so as to cover the ridge;
a step of exposing through a mask an area of the photoresist, covering part of an electrode layer at a top of the ridge, to form a resist pattern by development;
a step of applying a shrink material so as to cover the resist pattern;
a step of forming a crosslinked portion by reacting the shrink material with an acid remaining at an exposed interface of the resist pattern; and
a step of removing by etching an electrode layer exposed from a resist pattern having the crosslinked portion formed after an unreacted shrink material other than the reacted shrink material is stripping away.

2. The manufacturing method for semiconductor device of claim 1, wherein part of the electrode layer is a top layer of the ridge formed at a laser diode section on the InP substrate.

3. The manufacturing method for semiconductor device of claim 1, wherein the ridge includes a waveguide, and the waveguide and the electrode layer both are composed of InGaAs.

4. The manufacturing method for semiconductor device of claim 1, wherein the photoresist contains naphthoquinone diazide and a novolak resin.

5. The manufacturing method for semiconductor device of claim 2, wherein the ridge includes a waveguide, and the waveguide and the electrode layer both are composed of InGaAs.

6. The manufacturing method for semiconductor device of claim 2, wherein the photoresist contains naphthoquinone diazide and a novolak resin.

7. The manufacturing method for semiconductor device of claim 3, wherein the photoresist contains naphthoquinone diazide and a novolak resin.

8. The manufacturing method for semiconductor device of claim 5, wherein the photoresist contains naphthoquinone diazide and a novolak resin.
